(19) United States
(12) Patent Application Publication
(10) Pub. No.: US 2023/0376273 A1
(43) Pub. Date: Nov. 23, 2023

(54) BOOTH MULTIPLIER FOR COMPUTE-IN-MEMORY

(71) Applicant: Taiwan Semiconductor Manufacturing Company Limited, Hsinchu (TW)

(72) Inventors: Rawan Naous, Hsinchu (TW); Kerem Akarvardar, Hsinchu (TW); Hidehiro Fujiwara, Hsinchu (TW); Haruki Mori, Hsinchu (TW); Mahmut Sinangil, Campbell, CA (US); Yu-Der Chih, Hsinchu (TW)

(21) Appl. No.: 17/749,204

(22) Filed: May 20, 2022

(51) Int. Cl. G06F 7/527; G06F 7/508; G06F 7/544; H03K 19/20

(52) U.S. Cl. CPC G06F 7/5275; G06F 7/508; G06F 7/5443; H03K 19/20

(57) ABSTRACT

A compute-in-memory device may include a Booth encoder configured to receive at least one input of first bits, a Booth decoder configured to receive at least one weight of second bits and to output a plurality of partial products of the at least one input and the at least one weight, an adder configured to add a first partial product of the plurality of the partial products and a second partial product of the plurality of partial products before the Booth decoder generates a third partial product of the plurality of the partial products and to generate a plurality of sums of partial products, and a carry-lookahead adder configured to add the plurality of sums of partial products and to generate a final sum.

### BACKGROUND

Compute-in-memory (CIM) technology allows for faster processing of data loaded in main memory or cache than data in storage memory by reducing the latency caused by retrieving data from the storage memory for processing operations. Processing the data using CIM hardware located at the main memory or the cache allows for faster processing compared to processing data near or further from the main memory or the cache by communication caused latency between the memory main memory or the cache and the near or further processing hardware.

Digital CIM is processed in a bit-serial fashion. For example, a multiply-accumulate operation may be composed of a NOR gate for bit multiplication followed by an adder tree for accumulation. However, a bit-serial operation may be time consuming as a number of cycles that may be required for a computation is a function of a number of input bits. For example, the number of cycles required for a bit-serial operation may be equal to the number of input bits.

Typical Booth multipliers may operate in parallel with multiple stages required to produce the final product. To calculate a final product, a typical Booth multiplier may require all partial sums be generated in sequence prior to a shift and an addition operation may be applied to produce the final product. Therefore, there are multiple obstacles to implementing Booth multiplication in CIM.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a component block diagram illustrating a memory employing compute-in-memory (CIM) technology suitable for implementing various embodiments.

FIG. 2 is a component block diagram illustrating Booth encoding of input data for Booth multiplication in CIM suitable for implementing various embodiments.

FIG. 3 is a schematic circuit diagram illustrating a Booth encoder for Booth multiplication in CIM suitable for implementing various embodiments.

FIG. 4 is a table illustrating Booth encoding of input data for Booth multiplication in CIM suitable for implementing various embodiments.

FIG. 5 is a schematic circuit diagram illustrating circuitry for Booth multiplication of Booth encoded input data in CIM suitable for implementing various embodiments.

FIG. 6 is a schematic circuit diagram illustrating a Booth decoder for Booth multiplication in CIM suitable for implementing various embodiments.

FIG. 7 is a component block diagram illustrating a Booth multiplier in CIM suitable for implementing various embodiments.

FIG. 8 is a process flow diagram illustrating a method of Booth multiplication in CIM according to an embodiment.

FIG. 9 is a component block diagram of an example mobile computing device suitable for use with the various embodiments.

FIG. 10 is a component block diagram of an example computing device suitable for use with the various embodiments.

FIG. 11 is a component block diagram illustrating an example server suitable for use with the various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first element, component, and/or feature over or on a second element, component, and/or feature in the description that follows may include embodiments in which the first and second elements, components, and/or feature are formed in direct contact, and may also include embodiments in which additional elements, components, and/or feature are formed between the first and second features, such that the first and second elements, components, and/or feature are not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element's, components', and/or or feature's relationship to another element(s), component(s), and/or feature(s) as illustrated in the Figures. The spatially relative terms are intended to encompass different orientations of the device in use or operation in addition to the orientation depicted in the Figures. The apparatus and/or device may be otherwise oriented (rotated 90 degrees or at other orientations) and the spatially relative descriptors used herein may likewise be interpreted accordingly. Unless explicitly stated otherwise, each element, component, and/or feature having the same reference numeral refer to the same element, component, and/or feature, and is to have the same material composition and to have a thickness within a same thickness range.

The terms “processor,” “processor core,” “controller,” and “control unit” are used interchangeably herein, unless otherwise noted, to refer to any one or all of a software-configured processor, a hardware-configured processor, a general purpose processor, a dedicated purpose processor, a single-core processor, a homogeneous multi-core processor, a heterogeneous multi-core processor, a core of a multi-core processor, a microprocessor, a central processing unit (CPU), a graphics processing unit (GPU), a digital signal processor (DSP), etc., a controller, a microcontroller, a field programmable gate array (FPGA), an application-specific integrated circuit (ASIC), other programmable logic devices, discrete gate logic, transistor logic, and the like. A processor may be an integrated circuit, which may be configured such that the components of the integrated circuit reside on a single piece of semiconductor material, such as silicon.

The term “memory” is used herein, unless otherwise noted, to refer to any one or all of cache, main memory, random-access memory (RAM), including any variations of dynamic RAM (DRAM), synchronous DRAM (SDRAM), static RAM (SRAM), ferroelectric RAM (FeRAM), resistive RAM (RRAM), magnetoresistive RAM (MRAM), phase-change RAM (PCRAM), etc., flash memory, solid-state memory, and the like.

Digital CIM is processed in a bit-serial fashion. For example, a multiply-accumulate operation may be composed of a NOR gate for bit multiplication followed by an adder tree for accumulation. However, a bit-serial operation may be time consuming as a number of cycles that may be required for a computation is a function of a number of input bits. For example, the number of cycles required for a bit-serial operation may be equal to the number of input bits.

Typical Booth multipliers may operate in parallel with multiple stages required to produce a final product. Booth multipliers operate on the principles of Booth's algorithm that multiplies two signed binary numbers in 2's complement notation. As is typical in binary multiplication, Booth's algorithm generates partial products of the multiplication of a multiplicand by a multiplier that are shifted and summed to produce a final product. Booth's algorithm uses rules based on values of groups of bits of the multiplier to determine operations for generating the partial products using the multiplicand. The operation based on each group of bits may be implemented serially in by a typical Booth multiplier by inputting bits of the multiplicand and multiplier in to NOR gates and outputting the result to adders that generate partial sums. To calculate a final product, the typical Booth multiplier may require all partial sums be generated in sequence prior to a shift and an addition operation may be applied to produce the final product. This may significantly delay the processing of data and decrease computing speed. Therefore, there are multiple obstacles to implementing Booth multiplication in CIM.

Various embodiments described herein overcome the foregoing obstacles and enable improvements in computing speed and cost over typical Booth multiplier implementations. Various embodiments described herein include devices and methods for implementing a Booth multiplier for CIM. Various embodiments may include a Booth multiplier in CIM configured to implement Booth encoding and multi-cycle partial product generation enabling a reduction in hardware complexity and chip area as compared to typical Booth multiplier implementations.

The Booth multiplier may include a Booth encoder configured to implement Booth encoding. Various embodiments may be disclosed herein in relation to an example of 3-bit Booth encoding for 4-bit multiplication for clarity and ease of explanation. However, such descriptions are not intended to limit the scope of the claims and the enabling disclosures. One of skill in the art would realize that the disclosures herein may be similarly applied to Booth encoding of greater bit size or lesser bit size. Implementation of Booth encoding as a multiplication mode for digital CIM may replace multiplication of input data and weight data with multiplication of values derived from the input data (e.g., 0, 1, −1, 2, −2) and the weight data, where the values are indicated by a Booth encoded signal generated by encoding (e.g., 3-bit encoding) of an input sequence of the input data. A multiplexer/shifter may be implemented in CIM and configured to compute partial sums of the multiplication of multiple Booth encoded signals and the weight data. The Booth multiplier in CIM may enable a serial mode of Booth multiplication with the partial product generation, using the partial sums, and summation of the partial products over several cycles, compared to generating all partial products of the Booth multiplication prior to producing the final product as with typical Booth multiplier implementations.

As compared to typical Booth multiplier implementations, various embodiments of the Booth multiplier in CIM described herein may enable a reduction of a number of cycles required for computation. For example, where typical Booth multiplier implementations may require p cycles to execute a multiplication (where “p” is a number of input bits), various embodiments of Booth multiplier in CIM disclosed herein may execute a multiplication in p/2 cycles for signed inputs and p/2+1 cycles for unsigned computation. Other advantages of various embodiments disclosed herein over typical Booth multiplier implementations may include the ability to increase of trillions (or tera) operations per second (TOPS) per area. For example, the Booth multiplier in CIM may increase TOPS/mm² by approximately 10% for unsigned 4-bit input and approximately 60% for signed computation compared to N5 Digital implementation (i.e., based on a typical bit-serial operation with a NOR gate used for bit by bit multiplication followed by an adder tree starting with a 5-bit adder as the computation is based on using a 4-bit weight). Various embodiments of a Booth multiplier in CIM disclosed herein may reduce overall hardware complexity and may increase area efficiency in CIM as compared to typical Booth multiplier implementations.

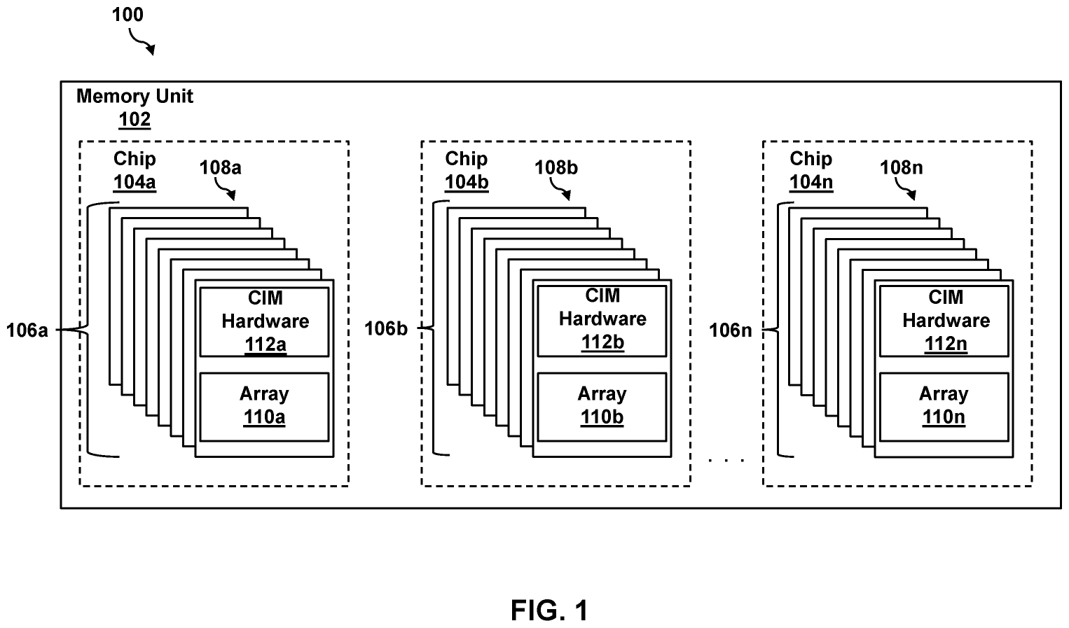

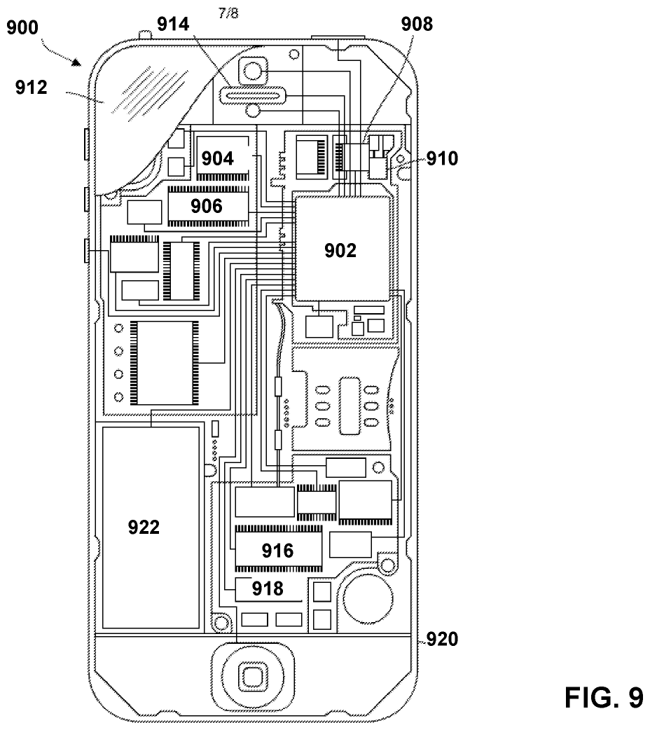

FIG. 1 illustrates an example memory 100 employing CIM technology suitable for implementing various embodiments. While FIG. 1 illustrates one example of a memory 100, one skilled in the art may recognize that additional components and/or elements may be added and existing components and/or element may be removed. Similarly, any such additional and existing components and/or elements may be combined and/or otherwise arranged. Additionally, the memory 100 may form part of or be integrated in another computing device or system, examples of which are described below with reference to FIGS. 9-11.

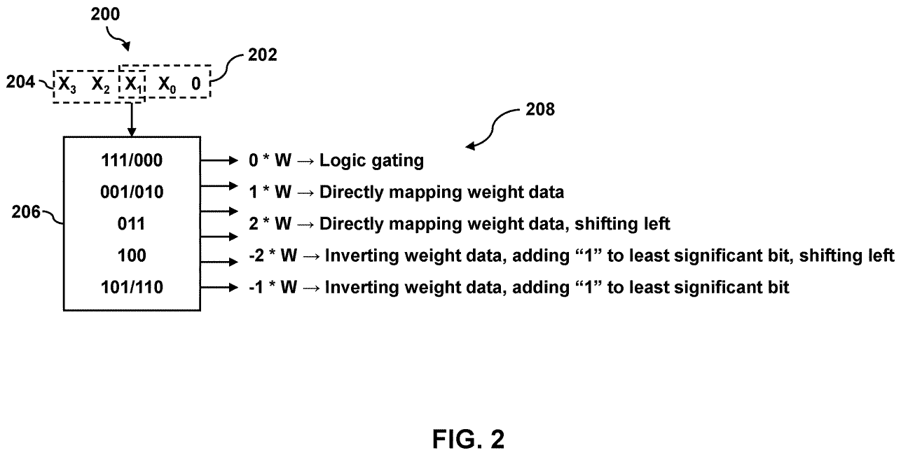

As illustrated in FIG. 1, in some embodiments, the memory 100 may include one or more memory units 102. A memory unit 102 may include any number of memory chips 104a-104n. Each of the memory chips 104a-104n may include a memory unit 108a-108n having any number of banks 106a-106n. Each of the banks 106a-106n may include a memory array 110a-110n and CIM hardware 112a-112n. Each memory array 110a-110n may include individual memory cells, arranged in columns and rows, configured to store data. Each of the banks 106a-106n may include CIM hardware 112a-112n configured to implement operations using the data stored at the banks 106a- 106n and/or memory arrays 110a-110n, as described further herein with reference to FIGS. 2-8. In some embodiments, a single bank of each group of banks 106a-106n may be implemented across multiple memory chips 104a-104n. In other words, a single bank may be part of multiple groups of banks 106a-106n. As such, a memory array 110a-110n and CIM hardware 112a-112n for each of the banks 106a-106n may also be implemented across the multiple memory chips 104a-104n.

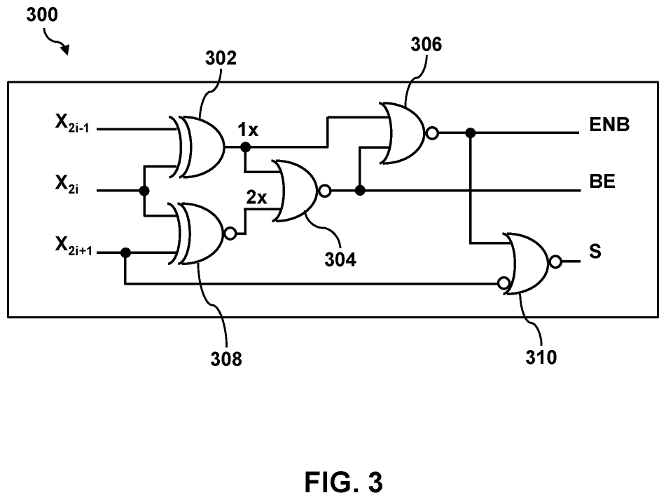

FIGS. 2-4 illustrate examples of the function and structure of a Booth encoder 206, 300 in CIM hardware 112a-112n. With reference to FIGS. 1-4, the Booth encoder 206, 300 may be one or more hardware components arranged in CIM hardware 112a-112n, described further herein with reference to FIG. 3, and configured to Booth encode input data 200 for a Booth multiplication operation executed in the CIM hardware 112a-112n, described further herein with reference to FIGS. 2-8. The examples described herein refer to a single booth encoder 206, 300 for ease of explanation and clarity. However, in various embodiments, multiple booth encoders 206, 300 may be employed in the CIM hardware 112a-112n to generate multiple Booth encoded signals 208 as described further herein.

FIG. 2 illustrates an example of Booth encoding of input data for Booth multiplication in CIM suitable for implementing various embodiments. With reference to FIGS. 1 and 2, the Booth encoder 206 may be configured to convert an input data 200 into Booth encoded signals 208. The Booth encoder 206 may encode the input data 200 in various cycles in which the Booth encoder 206 may encode subsets 202, 204 of the input data 200. Booth encoding the input data 200 may simplify the input data 200 by converting the input data to Booth encoded signals 208 associated with a limited number of operations for executing the Booth multiplication in the CIM hardware 112a-112n. As described further herein, the Booth encoder 206 may be a circuit of logic components (e.g., Booth encoder 300 in FIG. 3) configured to convert a subset 202, 204 to a Booth encoded signal 208. The Booth encoded signals 208 may be configured to control other parts of the CIM hardware 112a-112n configured for implementing a Booth multiplier, such as determining an operation for the Booth multiplier to execute and produce a partial sum, as described further herein. In some embodiments, the subsets 202, 204 of the input data 200 may overlap. In some embodiments, the subsets 202, 204 may be centered around a bit location and include a bit location immediately before the bit location and a bit location immediately after the bit location. For the subset 202 centered around a least significant bit of the input data 200, a “0” bit may be added to the input data 200 to fill the bit location immediately before the least significant bit.

Illustrated in FIG. 2 is a non-limiting example of 3-bit Booth encoding, encoding 3-bit subsets 202, 204 of the input data 200. A multiplication operation for execution by the CIM hardware 112a-112n may be a multiplication of an input data 200 and a weight data (not shown). The input data 200 may be of any bit length “p”, such that the input data 200 may include bits Xₚ₋₁, . . . , X₀. In the example illustrated in FIG. 2, the input data 200 is 4 bits and p=4. The Booth encoder 206 may encode 3-bit subsets 202, 204 of the input data 200 in various cycles. Each subset 202, 204 may be used to generate a Booth encoded signal 208. For example, the input data 200 may include bits X₃, X₂, X₁, X₀. A “0” bit may be added to the input data 200, for example, appended to a least significant bit X₀, so that the input data 200 may include bits X₃, X₂, X₁, X₀, 0. The “0” bit may be added to fill out the subset 202 centered around the least significant bit X₀. In this example, the subsets 202, 204 for 3-bit Booth encoding may each include bits centered at a bit location including a bit location immediately before the bit location and a bit location immediately after the bit location. Each successive subset 202, 204 may be centered at a bit location successive to the previous subset 202, 204. For example, the subsets 202, 204 may be expressed as bits X₂ᵢ₊₁, X₂ᵢ, and X₂ᵢ₋₁, where “i” may be a number of a cycle iteration. For a first cycle, e.g., i=0, there may not be an X₂ᵢ₋₁ bit, as there may not be a less significant bit than the least significant bit X₀, and the “0” bit appended to the least significant bit X₀ may be used instead. As successive subsets 202, 204 are centered at a bit location successive to the previous subset 202, 204, a least significant bit of a successive subset 202, 204 may overlap with a most significant bit of a previous subset 202, 204. In other words, the X₂ᵢ₋₁ bit of the successive subset 202, 204 and the X₂ᵢ₊₁ bit of the previous subset 202, 204 may overlap in successive iterations (e.g., bit X₂ᵢ₋₁ where i=1 and bit X₂ᵢ₊₁ where i=0 are both X₁ bit). As such, the Booth encoder 206 may encode 2 bits of the input data 200 that have not been previously encoded (e.g., bits X₂ᵢ₊₁, X₂ᵢ) and 1 bit of the input data 200 that has been previously encoded (e.g., bit X₂ᵢ₊₁) in successive iterations.

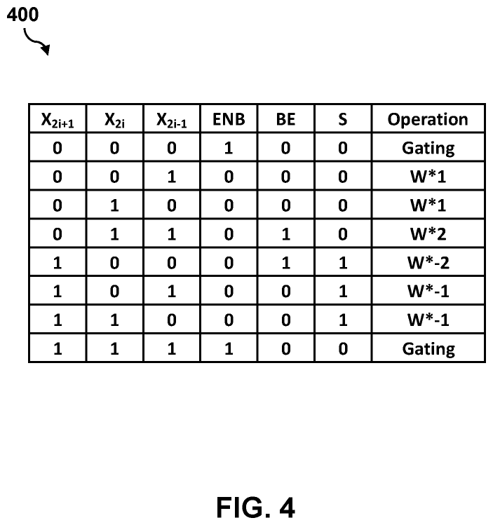

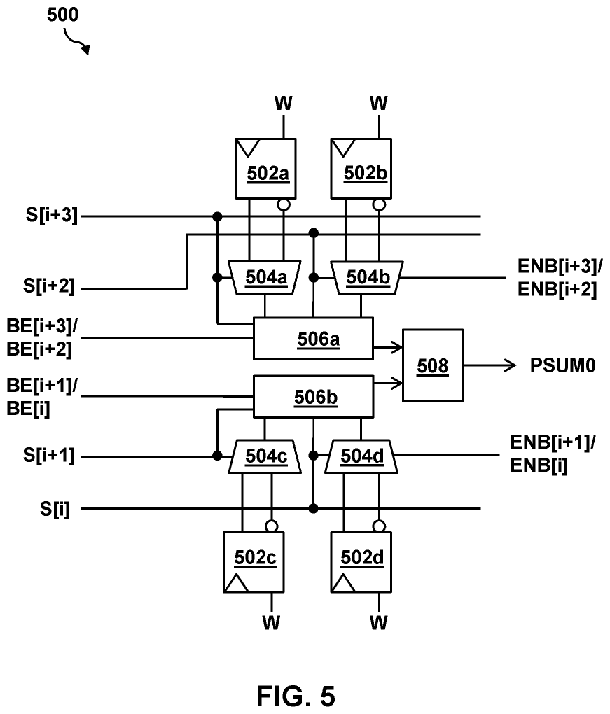

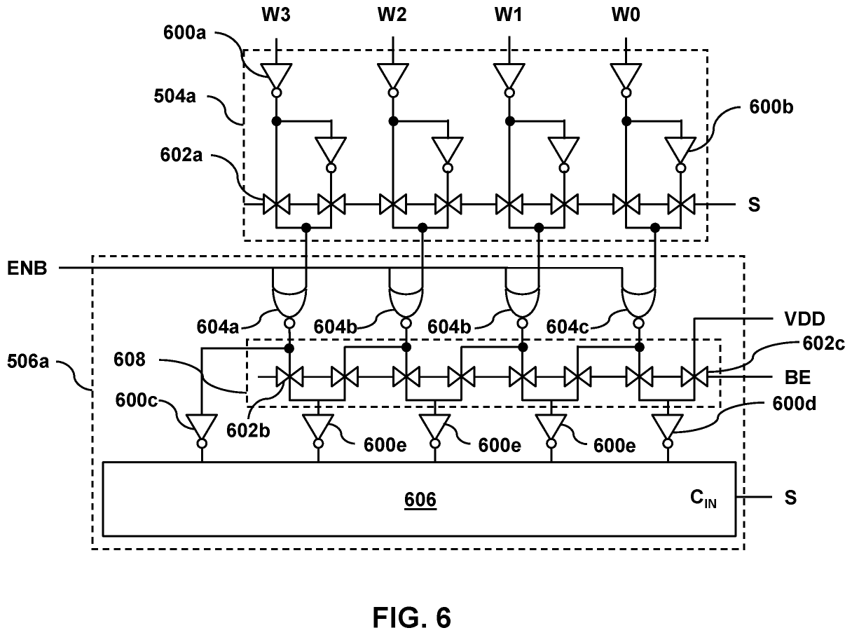

The Booth encoder 206 may generate Booth encoded signals 208, from the subsets 202, 204 of the input data 200 that may represent designated values configured to control CIM hardware 112a-112n to implement associated operations for executing the Booth multiplication in the CIM hardware 112a-112n. As described further herein, the Booth encoder 206 may be a circuit of logic components (e.g., Booth encoder 300 in FIG. 3) configured to convert a subset 202, 204 to a Booth encoded signal 208. The Booth encoded signal 208 may be a 3-bit signal for which each bit is configured to represent an instruction to the CIM hardware 112a-112n. The CIM hardware 112a-112n may receive the Booth encoded signal 208 and components of the CIM hardware 112a-112n (e.g., multiplexers 504a, 504b, 504c, 504d, and adders 506a, 506b in FIGS. 5 and 6) may respond to the Booth encoded signal 208 by implementing operations depending on the values of the bits of the Booth encoded signal 208 (e.g., as illustrated in table 400 in FIG. 4).

For example, from a subset 202, 204 of bits “111” and/or “000”, the Booth encoder 206 may generate a Booth encoded signal 208 that may represent a “0” value for multiplication with weight data (“W”), such as by indicating a logic gating operation in the CIM hardware 112a-112n to achieve the result of the multiplication. Logic gating in the CIM hardware 112a-112n may prevent bits of the weight data from propagating in the CIM hardware 112a-112n resulting in a “low” or “0” signal in place of the weight data, effectively multiplying the weight data by a “0” value.

From a subset 202, 204 of bits “001” and/or “010”, the Booth encoder 206 may generate a Booth encoded signal 208 that may represent a “1” value for multiplication with weight data, such as by indicating direct mapping of the weight data operation in the CIM hardware 112a-112n to achieve the result of the multiplication. Direct mapping in the CIM hardware 112a-112n may enable bits of the weight data to propagate in the CIM hardware 112a-112n unchanged resulting in signals representative of the unchanged weight data, effectively multiplying the weight data by a “1” value.

From a subset 202, 204 of bits “011”, the Booth encoder 206 may generate a Booth encoded signal 208 that may represent a “2” value for multiplication with weight data, such as by indicating a direct mapping of the weight data operation and left shift operation (e.g., left shift by 1 bit in an adder) on the weight data in the CIM hardware 112a-112n to achieve the result of the multiplication. Left shifting direct mapped weight data in the CIM hardware 112a-112n may shift bits of the weight data by an amount that changes the bits of the weight data resulting in signals representative of the weight data multiplied by a “2” value.

From a subset 202, 204 of bits “100”, the Booth encoder 206 may generate a Booth encoded signal 208 that may represent a “−2” value for multiplication with weight data, such as by indicating an inversion of the weight data operation, an addition operation of a “1” value at a least significant bit of the inverted weight data, and left shift operation (e.g., left shift by 1 bit in an adder) on the sum in the CIM hardware 112a-112n to achieve the result of the multiplication. Inverting bits of the weight data and addition of a “1” value at a least significant bit of the inverted bits of the weight data in the CIM hardware 112a-112n may generate signals representative of a negative signed version of the weight data, effectively multiplying the weight data by a “−1” value. Left shifting the negative signed version of the weight data in the CIM hardware 112a-112n may shift bits of the negative signed version of the weight data by an amount that changes the bits of the negative signed version of the weight data resulting in signals representative of the negative signed version of the weight data multiplied by a “2” value. Together, these operations may result in signals representative of the weight data multiplied by a “−2” value.

From a subset 202, 204 of bits “101” and/or “110”, the Booth encoder 206 may generate a Booth encoded signal 208 that may represent a “−1” value for multiplication with weight data, such as by indicating an inversion of the weight data operation and an addition operation of a “1” value at a least significant bit of the inverted weight data in the CIM hardware 112a-112n to achieve the result of the multiplication. Inverting bits of the weight data and addition of a “1” value at a least significant bit of the inverted bits of the weight data in the CIM hardware 112a-112n may generate signals representative of a negative signed version of the weight data, effectively multiplying the weight data by a “−1” value.

Compared to bit by bit multiplication, 3-bit Booth encoding for 4-bit multiplication may reduce processing time for a multiplication by approximately half. Rather than 4 cycles to multiply each bit of the input data 200 by a weight data as in bit by bit multiplication, the 3-bit Booth encoding may encode the input data 200 in 2 cycles, using two 3-bit subsets 202, 204, to generate the Booth encoded signals 208 configured to control the CIM hardware 112a-112n to achieve the result of the multiplication.

FIG. 3 illustrates a schematic circuit diagram of an implementation of a Booth encoder 300 (e.g., Booth encoder 206) for Booth multiplication in CIM suitable consistent with various embodiments. With reference to FIGS. 1-3, the Booth encoder 300 may be included in the CIM hardware 112a-112n, such as coupled to a Booth multiplier as described further herein.

Illustrated in FIG. 3 is a non-limiting example of a 3-bit Booth encoder 300 for 3-bit Booth encoding, as described herein, for example, with reference to FIG. 2., encoding 3-bit subsets 202, 204 of the input data 200. In some embodiments, multiple 3-bit Booth encoders 300 may be coupled to a 4-bit Booth multiplier. The Booth encoder 300 may include input bit lines configured to carry signal representing the bits of the subsets 202, 204 of the input data 200 (e.g., bits X₂ᵢ₊₁, X₂ᵢ, and X₂ᵢ₋₁, as described with reference to FIG. 2). A first input bit line carrying a first signal representing a first bit of a subset 202, 204 (e.g., X₂ᵢ₋₁) and a second input bit line carrying a second signal representing a second bit of the subset 202, 204 (e.g., X₂ᵢ) may be coupled to an input end of an exclusive OR (“XOR”) gate 302. The XOR gate 302 may receive the first signal and the second signal as inputs, and generate an output as a first intermediary signal (“1x”). The second bit line and a third bit line carrying a third signal representing a third bit of the subset 202, 204 (e.g., X₂ᵢ₊₁) may be coupled to an input end of an exclusive NOR (“XNOR”) gate 308. The XNOR gate 308 may receive the second signal and the third signal as inputs, and generate an output as a second intermediary signal (“2x”).

A first NOR gate 304 may be coupled to an output end of the XOR gate 302 and an output end of the XNOR gate 308 to receive as inputs to the first NOR gate 304. Thus, the first NOR gate 304 may receive the first intermediary signal 1x from the XOR gate 302 and the second intermediary signal 2x from the XNOR gate 308 as inputs. The first NOR gate 304 may generate an output as a Booth encoded bit (“BE”).

A second NOR gate 306 may be coupled to the output end of the XOR gate 302 to receive the first intermediary signal 1x as an input as well as an output end of the first NOR gate 304 to receive the Booth encoded bit BE as inputs to the second NOR gate 306. Thus, the second NOR gate 306 may receive the first intermediary signal 1x from the XOR gate 302 and the Booth encoded bit BE from the first NOR gate 304 as inputs. The second NOR gate 306 may generate an output as an enable bit (“ENB”).

A third NOR gate 310 may be coupled to an output end of the second NOR gate 306 at an input end of the third NOR gate 310 to receive the ENB as an input. The third NOR gate 310 may also be coupled to the third bit line at an inverted input end to receive the inverse of the third bit line as an input. For example, an inverted may be coupled between the third bit line and the input end of the third NOR gate 310. Thus, the third NOR gate 310 may receive the enable bit ENB from the second NOR gate 306 and the third signal representing an inverse of the third bit of the subset 202, 204 from the third bit line as inputs. In some embodiments the third NOR gate 310 may invert the third signal. In some embodiment, the third NOR gate 310 may receive an inverted third signal from the inverter. The third NOR gate 310 may generate an output as a select bit (“S”).

The Booth encoder 300 may generate and output a Booth encoded signal 208 from a subset 202, 204 of the input data 200. A Booth encoded signal 208 may be any combination of binary bits. For example, the Booth encoded signal 208 may be 3-bit Booth encoded signals 208. The Booth encoded signal 208 may include the enable bit, the Booth encoded bit, and the select bit.

Illustrated in FIG. 4 is a non-limiting example of a table 400 of Booth encoding of the subset 202, 204 of the input data 200 (e.g., X₂ᵢ₊₁, X₂ᵢ, and X₂ᵢ₋₁) generating the Booth encoded signal 208, including the enable bit (“ENB”), the Booth encoded bit (“BE”), and the select bit (“S”) for Booth multiplication in CIM suitable for implementing various embodiments, with reference to FIGS. 1-4. The example illustrated in FIG. 4 may be implemented by the Booth encoder 206, 300.

In the example illustrated in FIG. 4, the Booth encoder 206, 300 receiving the subset 202, 204 of bits “000” and/or “111” may generate and output the Booth encoded signal 208 (e.g., ENB, BE, S) of bits “100”, which may be configured to cause other parts of the CIM hardware 112a-112n to execute multiplication of a “0” value with weight data (“W”), such as by a logic gating operation in the CIM hardware 112a-112n to achieve the result of the multiplication. The CIM hardware 112a-112n may be configured to interpret/be controlled by the Booth encoded signal 208 of bits “100” to perform logic gating of the weight data. Logic gating in the CIM hardware 112a-112n may prevent bits of the weight data from propagating in the CIM hardware 112a-112n resulting in a “low” or “0” signal in place of the weight data, effectively multiplying the weight data by a “0” value.

The Booth encoder 206, 300 receiving the subset 202, 204 of bits “001” and/or “010” may generate and output the Booth encoded signal 208 of bits “000”, which may be configured to cause other parts of the CIM hardware 112a-112n to execute multiplication of a “1” value with weight data, such as by a direct mapping of the weight data operation in the CIM hardware 112a-112n to achieve the result of the multiplication. The CIM hardware 112a-112n may be configured to interpret/be controlled by the Booth encoded signal 208 of bits “000” to perform direct mapping of the weight data. Direct mapping in the CIM hardware 112a-112n may enable bits of the weight data to propagate in the CIM hardware 112a-112n unchanged resulting in signals representative of the unchanged weight data, effectively multiplying the weight data by a “1” value.

The Booth encoder 206, 300 receiving the subset 202, 204 of bits “011” may generate and output the Booth encoded signal 208 of bits “010”, which may be configured to cause other parts of the CIM hardware 112a-112n to execute multiplication of a “2” value with weight data, such as by a direct mapping of the weight data operation and left shift operation (e.g., left shift by 1 bit in an adder) on the weight data in the CIM hardware 112a-112n to achieve the result of the multiplication. The CIM hardware 112a-112n may be configured to interpret/be controlled by the Booth encoded signal 208 of bits “010” to perform direct mapping and shifting of the weight data. Left shifting direct mapped weight data in the CIM hardware 112a-112n may shift bits of the weight data by an amount that changes the bits of the weight data resulting in signals representative of the weight data multiplied by a “2” value.

The Booth encoder 206, 300 receiving the subset 202, 204 of bits “100” may generate and output the Booth encoded signal 208 of bits “011”, which may be configured to cause other parts of the CIM hardware 112a-112n to execute multiplication of a “−2” value with weight data, such as by an inversion of the weight data operation, an addition operation of a “1” value at a least significant bit of the inverted weight data, and left shift operation (e.g., left shift by 1 bit in an adder) on the sum in the CIM hardware 112a-112n to achieve the result of the multiplication. The CIM hardware 112a-112n may be configured to interpret/be controlled by the Booth encoded signal 208 of bits “011” to perform inversion of the weight data, addition to the weight data, and shifting of the weight data. Inverting bits of the weight data and addition of a “1” value at a least significant bit of the inverted bits of the weight data in the CIM hardware 112a-112n may generate signals representative of a negative signed version of the weight data, effectively multiplying the weight data by a “−1” value. Left shifting the negative signed version of the weight data in the CIM hardware 112a-112n may shift bits of the negative signed version of the weight data by an amount that changes the bits of the negative signed version of the weight data resulting in signals representative of the negative signed version of the weight data multiplied by a “2” value. Together, these operations may result in signals representative of the weight data multiplied by a “−2” value.

The Booth encoder 206, 300 receiving the subset 202, 204 of bits “101” and/or “110” may generate and output the Booth encoded signal 208 of bits “001”, which may be configured to cause other parts of the CIM hardware 112a-112n to execute multiplication of a “−1” value with weight data, such as by an inversion of the weight data operation and an addition operation of a “1” value at a least significant bit of the inverted weight data in the CIM hardware 112a-112n to achieve the result of the multiplication. The CIM hardware 112a-112n may be configured to interpret/be controlled by the Booth encoded signal 208 of bits “001” to perform inversion of the weight data and addition to the weight data. Inverting bits of the weight data and addition of a “1” value at a least significant bit of the inverted bits of the weight data in the CIM hardware 112a-112n may generate signals representative of a negative signed version of the weight data, effectively multiplying the weight data by a “−1” value.

FIG. 5 illustrates an example of CIM hardware 500 for Booth multiplication in CIM suitable for implementing various embodiments. With reference to FIGS. 1-5, the CIM hardware 500 may be included in the CIM hardware 112a-112n, such as coupled to the Booth encoder 206, 300 as described further herein.

Illustrated in FIG. 5 is a non-limiting example of the CIM hardware 500 configured to be included as part of a 4-bit Booth multiplier. The CIM hardware 500 may include 4 registers 502a, 502b, 502c, 502d, 4 multiplexers 504a, 504b, 504c, 504d, and 3 adders 506a, 506b, 508.

Each register 502a, 502b, 502c, 502d may be coupled to a multiplexer 504a, 504b, 504c, 504d. In some embodiments, the registers 502a, 502b, 502c, 502d may include multiple outputs, such as a non-inverted output (or output) and an inverted output. Each register 502a, 502b, 502c, 502d may be coupled to one or more inputs of a multiplexer 504a, 504b, 504c, 504d via one or more of the output and the inverted output. In some embodiments, an inverter may be coupled between an output of a register 502a, 502b, 502c, 502d and an input of a multiplexer 504a, 504b, 504c, 504d to produce the inverted output. Each register 502a, 502b, 502c, 502d may receive a weight data (“W”) and output the weight data and/or an inverse of the weight data to the inputs of a multiplexer 504a, 504b, 504c, 504d. In some embodiments, the weight data may be one or more bits of weight data, such as 4-bit weight data. While FIG. 5 illustrates the multiplexer 504a, 504b, 504c, 504d to be 2×1 multiplexers, other multiplexers may be implemented. For example, 4×1, 4×2, etc. multiplexers may be used.

Each multiplexer 504a, 504b, 504c, 504d may be coupled at a select line to a select signal (e.g., select bit “S”) that may be outputted by one of multiple Booth encoders 206, 300. In some embodiments, each subset 202, 204 of the input data 200 may be input to one of the multiple Booth encoders 206, 300, and each of the multiple Booth encoders 206, 300 may output a select signal (e.g., S[i], S[i+1], S[i+2], S[i+3], where “i” may be a number of a cycle iteration) generated using the input subset 202, 204 of the input data 200. In some embodiments, each multiplexer 504a, 504b, 504c, 504d may be configured to receive a select signal for a different subset 202, 204 of the input data 200. For example, the select signal may be configured to cause the multiplexer 504a, 504b, 504c, 504d to select which one of the inputs of each respective multiplexer 504a, 504b, 504c, 504d (i.e., the weight data or the inverse of the weight data) to output to an adder 506a, 506b from an output of the multiplexer 504a, 504b, 504c, 504d. In some embodiments, the multiplexer 504a, 504b, 504c, 504d may directly map the weight data to the adder 506a, 506b. For example, the multiplexer 504a, 504b, 504c, 504d may directly map the weight data to the adder 506a, 506b in response to the select signal being a “0” value. In some embodiments, the multiplexer 504a, 504b, 504c, 504d may provide the inverse of the weight data to the adder 506a, 506b. For example, the multiplexer 504a, 504b, 504c, 504d may provide the inverse of the weight data to the adder 506a, 506b in response to the select signal being a “1” value.

The adders 506a, 506b may be of any bit size, such as 6-bit adders. Each adder 506a, 506b may be coupled to one or more multiplexers 504a, 504b, 504c, 504d, such as 2 multiplexers 504a, 504b, 504c, 504d, at an input. The adder 506a, 506b may receive the output of the multiplexers 504a, 504b, 504c, 504d at the input. Each adder 506a, 506b may also be coupled at a control line to receive the enable bit (e.g., enable bit “ENB”) output from one of the multiple Booth encoders 206, 300. In some embodiments, each of the multiple Booth encoders 206, 300 may output an enable bit (e.g., ENB[i], ENB [i+1], ENB [i+2], ENB [i+3], where “i” may be a number of a cycle iteration) generated using the input subset 202, 204 of the input data 200. In some embodiments, each adder 506a, 506b may be configured to receive one or more enable bits for different subsets 202, 204 of the input data 200. For example, each adder 506a, 506b may be configured to receive two enable bits (ENB). An ENB bit received by an adder 506a, 506b may be trigger the adder 506a, 506b to execute the add functions. For example, the enable encoded bit may be configured to cause the adder 506a, 506b to execute a gating operation on the output of the multiplexers 504a, 504b, 504c, 504d received by the adder 506a, 506b. For example, the adder 506a, 506b may execute a gating operation on the output of the multiplexers 504a, 504b, 504c, 504d received by the adder 506a, 506b in response to the enable bit a “1” value. The gating operation may set the inputs to the adder 506a, 506b to a value of “0” regardless of the value of the output of the multiplexers 504a, 504b, 504c, 504d.

Each adder 506a, 506b may also be coupled at a control line to receive the Booth encoded bit (e.g., Booth encoded bit “BE”) output from one of the multiple Booth encoders 206, 300. In some embodiments, each of the multiple Booth encoders 206, 300 may output a Booth encoded bit (e.g., BE[i], BE[i+1], BE[i+2], BE[i+3], where “i” may be a number of a cycle iteration) generated using the input subset 202, 204 of the input data 200. In some embodiments, each adder 506a, 506b may be configured to receive one or more Booth encoded bits for different subsets 202, 204 of the input data 200. For example, each adder 506a, 506b may be configured to receive two Booth encoded bits (BE). A BE bit received by an adder 506a, 506b may be trigger the adder 506a, 506b to execute the add functions. For example, the Booth encoded bit may be configured to cause the adder 506a, 506b to execute a left shift operation (e.g., left shift by 1 bit) on the weight data received by the adder 506a, 506b. For example, the adder 506a, 506b may execute a left shift operation on the weight data received by the adder 506a, 506b in response to the Booth encoded bit being a “1” value. The shift may be used to implement a multiplication of the weight data by a value of “2”.

Each adder 506a, 506b may be configured to receive one or more of the select signals for the different subsets 202, 204 of the input data 200 at a select line. For example, each adder 506a, 506b may be configured to receive two select signals (S). A select signal received by an adder 506a, 506b may be used by the adder 506a, 506b as a carry in (C_{IN}) value for use in an addition with a least significant bit of a value at the adder 506a, 506b.

The adders 506a, 506b may output the results of their operations as inputs to an adder 508. The adder 508 may sum the results received at the inputs and generate a partial sum (PSUM0) of the Booth multiplication of the subsets 202, 204 of the input data 200 and the weight data.

Typical implementations of Booth multiplication use different construction from the described embodiments. In particular, typical implementations of Booth multiplication typically utilize NOR gates in place of each of the multiplexers 504a, 504b, 504c, 504d. Various embodiments described herein utilize the multiplexers 504a, 504b, 504c, 504d, which may enable an approximately 50% reduction in delay with executing at least two cycles for signed computation in comparison to typical implementations utilizing NOR gates. The delay reduction may be achieved by using Booth encoding to convert the input data for use in reducing the number of operations for achieving the multiplication. Multiple bits of the input data may be Booth encoded, and the resulting encoded bits may be used to execute calculations for the multiple bits, rather than bit-by-bit calculations executed by typical implementations.

FIG. 6 illustrates a schematic circuit of the multiplexer (e.g., 504a) and adder (e.g., 506a) used in the CIM hardware for Booth multiplication in CIM suitable for implementing various embodiments. With reference to FIGS. 1-6, the CIM hardware (multiplexer, shifter adder) for Booth multiplication may be included in the CIM hardware 112a-112n, such as coupled to the Booth encoder 206, 300 as described further herein. The CIM hardware for Booth multiplication may include the multiplexer 504a (used here as a representative example of any of the multiplexers 504a, 504b, 504c, 504d) and the adder 506a (used here as a representative example of any of the 506a, 506b). Illustrated in FIG. 6 is a non-limiting example of the CIM hardware configured to be included as part of a 4-bit Booth multiplier.

The multiplexer 504a may be coupled, at an input, to any number of input lines configured to carry weight data. For example, the multiplexer 504a may be coupled to four input lines configured to carry weight data (e.g., W3, W2, W1, W0). The multiplexer 504a may include multiple inverters 600a, 600b, which may be configured to function as buffers for temporary storage of the weight data. For example, one inverter 600a, 600b may be configured to temporarily store the weight data, and another inverter 600a, 600b may be configured to temporarily store the inverse of the weight data.

The multiplexer 504a may be coupled, at a select line, to a select signal (e.g., select bit “S”) output by the Booth encoder 206, 300. The multiplexer 504a may include multiple transmission gates 602a coupled between the inverters 600a, 600b and outputs of the multiplexer 504a. The transmission gates 602a may also be coupled, at an input, to the select signal. The select signal may determine which of the input signal or the inverse of the input signal of each of the input weight data (e.g., W3, W2, W1, W0) to output from the multiplexer 504a. In some embodiments, pairs of the transmission gates 602a, coupled to the same output of the multiplexer 504a may be differently configured to respond to the select signal. For example, a transmission gate 602a may enable transmission of the weight data and/or inverse of the weight data stored at the inverter 600a and another transmission gate 602a may prevent transmission of the weight data and/or inverse of the weight data stored at the inverter 600b for the same select signal, and vice versa. The multiplexer 504a may output weight data and/or inverse of the weight data at an output as controlled by the select signal.

The adder 506a may receive, at an input, the weight data and/or inverse of the weight data (collectively referred to herein as weight data for the adder 506a) output by the multiplexer 504a. The adder 506a may be coupled to an enable signal (e.g., enable bit “ENB”) that may be outputted from the Booth encoder 206, 300. The enable signal may trigger the adder 506a to add the signal received at the inputs to a value held in an adder component 606 (i.e., shift register). The adder 506a may include multiple NOR gates 604a, 604b, 604c configured to receive the weight data at one input and the enable signal at a second input of the NOR gates 604a, 604b, 604c. The NOR gates 604a, 604b, 604c may be configured to NOR the weight data and the enable signal such that the enable signal may control a logic gating operation of the adder 506a. For example, an enable signal configured to enable logic gating (e.g., enable signal is a “1” value), the NOR gates 604a, 604b, 604c may only output “0” values regardless of the value of the weight data. Otherwise, the NOR gates 604a, 604b, 604c may output the weight data at the input and the enable signal configured not to enable logic gating (e.g., enable signal is a “0” value).

A control of the adder 506a may be coupled to a Booth encoded bit (e.g., Booth encoded bit “BE”) that is output by the Booth encoder 206, 300. The Booth encoded bit may be configured to control whether the adder 506a executes a shift left operation (e.g., shift left 1 bit). The output of each NOR gate 604a, 604b, 604c may be coupled to a shifter 608. The shifter 608 may include multiple transmission gates 602b configured to couple the output of each NOR gate 604b to multiple inverters 600e. In addition, shifter 608 may be configured to directly couple an inverter 600c to the output of the NOR gate 604a and may include a transmission gate 602b configured to couple the output of the NOR gate 604a to an inverter 600e. The NOR gate 604a may be associated with an input of a most significant bit of the weight data. The inverter 600e coupled to the NOR gate 604a may correspond with a most significant bit position of the weight data, and the inverter 600c coupled to the NOR gate 604a may correspond with a more significant bit position that the most significant bit position of the weight data. The shifter 608 may include a transmission gate 602b configured to couple the output of the NOR gate 604c to an inverter 600e and a transmission gate 602b configured to couple the output of the NOR gate 604c to an inverter 600e. The NOR gate 604c may be associated with an input of a least significant bit of the weight data. The inverter 600d coupled to the NOR gate 604c may correspond with a least significant bit position of the weight data. The adder 506a may also be coupled to a supply voltage (VDD). The shifter 608 may include a transmission gate 602c configured to couple the supply voltage VDD to the inverter 600d.

The transmission gates 602b and 602c may also be coupled to the Booth encoded (BE) bit. The transmission gates 602b may be configured to enable and/or prevent transmission of the output from the NOR gates 604a, 604b, 604c to the inverters 600e, 600d. The transmission gate 602c may be configured to enable and/or prevent transmission of the supply voltage to the inverter 600d. In some embodiments, pairs of the transmission gates 602b, 602c, coupled to the same inverters 600e, 600d may be differently configured to respond to the Booth encoded bit. For example, a transmission gate 602b may enable transmission of the output from the NOR gate 604a, 604b, 604c to the inverters 600e, 600d associated with the same bit position of the weight data, while another transmission gate 600e may prevent transmission of the output of the NOR gate 604b, 604c to the inverters 600e associated with the different bit positions of the weight data, and vice versa. The transmission gate 602c may enable transmission of the supply voltage to the inverter 600d and the transmission gates 602b may enable transmission of the output of the NOR gates 604b, 604c to the inverters 600e associated with the different bit position of the weight data in response to the same Booth encoded bit value. The different bit position of the weight data may be a more significant bit position associated with the inverters 600e than the bit position of the weight data associated with the NOR gate 604b, 604c. The inverter 600c may be associated with the different, more significant bit position of the weight data than the bit position of the weight data associated with the NOR gate 604a. Enabling transmission of the supply voltage to the inverter 600d by transmission gate 602b, transmission of the output of the NOR gates 604b, 604c to the inverters 600e associated with the different bit position of the weight data by the transmission gates 602b, 602c, and transmission of the output of the NOR gate 604a to the inverter 600c may enable a left shift of the weight data in the adder 506a. In some embodiments, the shifter 608 may include the NOR gate 604a, 604b, 604c. In some embodiments, the shifter 608 may include the inverters 600c, 600d, 600e.

An adder component 606 of the adder 506a may receive data temporarily stored at the inverters 600c, 600d, 600d. The adder component 606 may also receive, at an input (C_{IN}), the select signal from the Booth encoder 300. The adder component 606 may be configured to sum the data received from the inverters 600c, 600d, 600e. In response to a designated value of the select signal (e.g., select signal is a “1” value) the adder component 606 may add a “1” value, as a C_{IN} bit, to the least significant bit of the sum. The adder 506a and the adder component 606 may be configured to output the sum at an output. For example, the sum may be output to the adder 508 and used to generate the partial sum (PSUMO).

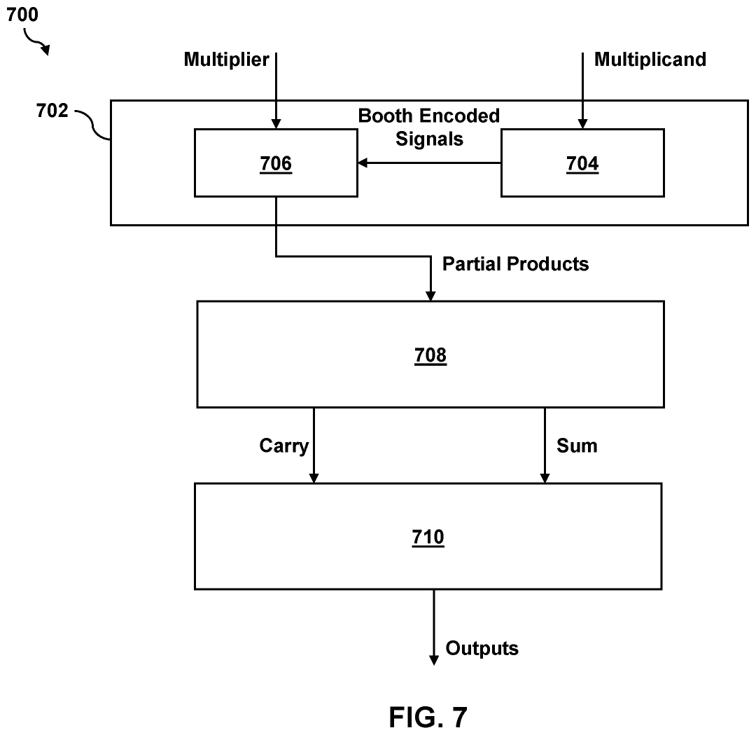

FIG. 7 illustrates an example of a Booth multiplier 700 in CIM suitable for implementing various embodiments. With reference to FIGS. 1-7, the Booth multiplier 700 may be included in the CIM hardware 112a-112n. The Booth multiplier 700 may include the Booth algorithm hardware 702, including a Booth encoder 704 (e.g., Booth encoder 206, 300), a Booth decoder 706 (e.g., CIM hardware 500), a compressor 708, and a carry-lookahead adder 710.

As described herein, the Booth encoder 704 may receive a multiplicand (e.g., input data 200 and/or a subset of input data 202, 204 of the input data). The Booth encoder 704 may be a circuit of logic components (e.g., Booth encoder 300 in FIG. 3) that may generate and output a Booth encoded signal (e.g., Booth encoded signal 208, which may include the enable bit, the Booth encoded bit, and the select bit) from the multiplicand. The Booth decoder 706 may be a circuit of logic components (e.g., CIM hardware 500 in FIG. 5, including multiplexers 504 and adders 506 in FIGS. 5 and 6) that may receive a multiplier (e.g., weight data), and generate and output at least two partial products of the weight data manipulated by operations for executing the Booth multiplication in the CIM hardware 700 in response to receiving an associated Booth encoded signal. Each partial product may be a result of the manipulation of the weight data in response to a respective Booth encoded signal 208. Multiple partial products may be generated based on a length of the multiplicand and the number of Booth encoded signals 208 needed to represent the entire multiplicand. For example, for 32-bit multiplication of a 32-bit multiplicand using 3-bit Booth encoding, where the sequence for 3-bit Boothe encoding of the multiplicand may use bits X₂ᵢ₊₁, X₂ᵢ, and X₂ᵢ₋₁ per cycle, where “i” may be a number of a cycle iteration, the Booth decoder 706 may receive 18 Booth encoded signals 208 and generate 18 partial products.

The compressor 708 may receive the partial products of the Booth algorithm hardware 702 and sum the partial products. The compressor may generate and output a sum of the partial products (sum) and/or a carry bit (carry). In some embodiments, the compressor 708 may be any type of compressor 708, such as a Wallace tree. The compressor 708 may sum partial products prior to the Booth algorithm hardware 702 generating and outputting all of the partial products for a Booth multiplication.

A carry-lookahead adder 710 may receive the partial products (sum) and/or a carry bit (carry) from the compressor 708. The carry-lookahead adder 710 summing the received partial products and/or carry bits may generate and output a final output of the Booth multiplication. The summed partial products received from the compressor 708 may be received as they become available. As with the compressor 708, the carry-lookahead adder 710 may receive the summed partial products prior to the Booth algorithm hardware 702 generating and outputting all of the partial products for the Booth multiplication. The carry-lookahead adder 710 may sum each of the received partial products with a sum of prior received partial products until all of the partial products are received, and output a final sum of the received partial products as the final output of the Booth multiplication.

The components of the Booth multiplier 700, including any of the Booth encoder 702, the Booth decoder 704, the compressor 706 and the carry-lookahead adder 708 may implement operations for Booth multiplication prior to receiving all of the data for Booth multiplication of the input data 200 and the weight data. The components of the Booth multiplier 700 may be configured to implement operations for Booth multiplication on, for example, a per cycle basis where each cycle Booth encodes a subset 202, 204 of the input data 200 and uses a Booth encoded signal 208 generated from the encoding. As such, components of the Booth multiplier 700 may be configured to implement operations for the Booth multiplication for each received subset 202, 204 of the input data 200. The Booth encoder 702 may only require the subset 202, 204 of the input data 200 relevant for the cycle being implemented. The Booth decoder 704 may manipulate weight data based on the Booth encoded signal 208 for the relevant cycle and produce partial products. The compressor 706 may sum the partial products of the relevant cycle to produce a sum of the partial products. The carry-lookahead adder 708 may sequentially sum the sum of the partial products output by the compressor 706 for sequential cycles to output the final sum of the received sums of partial products as the final output of the Booth multiplication.

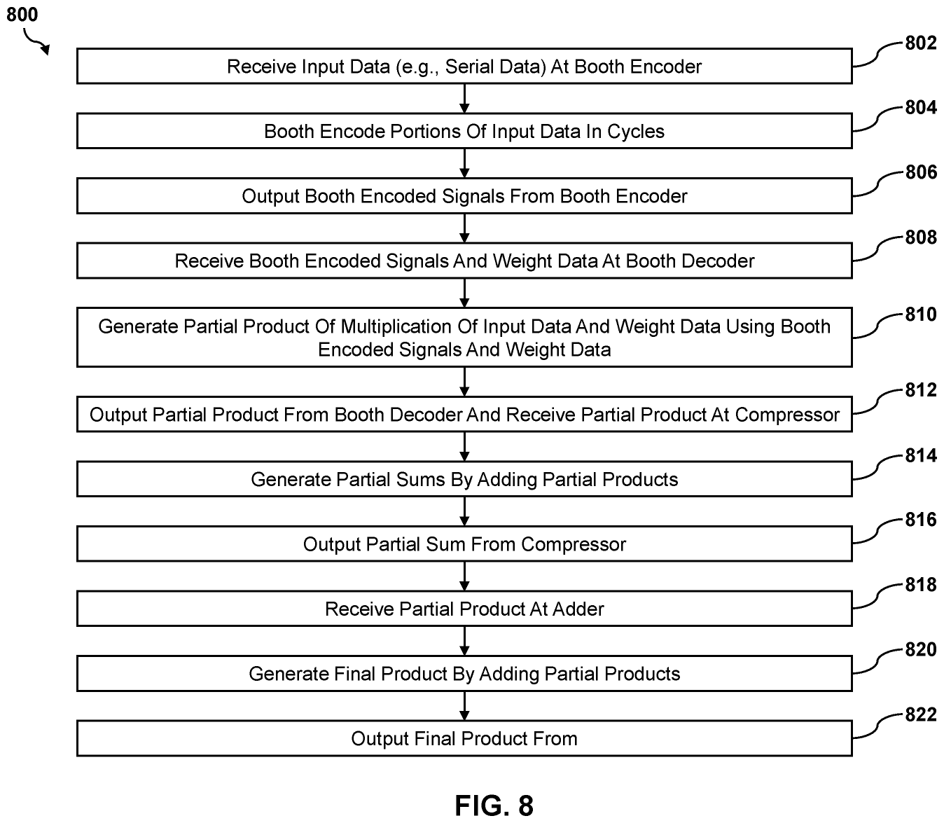

FIG. 8 illustrates a method 800 for Booth multiplication in CIM in accordance with various embodiments. With reference to FIGS. 1-8, the method 800 may be implemented in CIM hardware 112a-112n, 500, including any of a Booth encoder 206, 300, 704, a Booth decoder 706, a multiplexer 504a, 504b, 504c, 504d, an adder 506a, 506b, 508, a compressor 708, a carry-lookahead adder 710, and/or components thereof. In order to encompass the alternative configurations enabled in various embodiments, the hardware implementing the method 800 is referred to herein as a “CIM device.” In some embodiments, any of blocks 802-820 may be implemented continually or periodically throughout the processes of implementing the method 800 until implementation of block 822.

In block 802, the CIM device may receive input data 200 at the Booth encoder 206, 300, 704. The input data 200 may be serial data, subsets 202, 204 of which may be received continually or periodically throughout the processes of implementing the method 800 until all of the input data 200 is received.

In block 804, the CIM device may Booth encode portions of the input data 200, received in block 802, in cycles. Subsets 202, 204 of the input data received at the Booth encoder 206, 300, 704 may be convert to Booth encoded signals 208 through various logic operations of various logic components, as illustrated in FIG. 3. For example, each cycle may be used to Booth encode a subset 202, 204 of the input data 200 by the Booth encoder 206, 300, 704. In some embodiments, the subsets 202, 204 may be 3-bit portions of the input data 200.

Booth encoding the portions of the input data may convert the portions to Booth encoded signals 208 associated with a limited number of operations for executing the Booth multiplication in the CIM hardware 112a-112n, 500, 700. The Booth encoded signals 208 may be configured to control other parts of the CIM hardware 112a-112n, 500, 700, including the multiplexers 504a, 504b, 504c, 504d, the adders 506a, 506b, and/or the Booth decoder 706, configured for implementing a Booth multiplier, such as determining an operation for the Booth multiplier to execute and produce a partial sum. For example, the Booth encoder 206, 300, 704 receiving the subset 202, 204 of bits “000” and/or “111” may generate and output the Booth encoded signal 208 of bits “100”, which may be configured to cause other parts of the CIM hardware 112a-112n, 500, 700 to execute multiplication of a “0” value with weight data (“W”), such as by a logic gating operation in the CIM hardware 112a-112n, 500, 700 to achieve the result of the multiplication. The CIM hardware 112a-112n, 500, 700 may be configured to interpret/be controlled by the Booth encoded signal 208 of bits “100” to perform logic gating of the weight data. Logic gating in the CIM hardware 112a-112n, 500, 700 may prevent bits of the weight data from propagating in the CIM hardware 112a-112n, 500, 700 resulting in a “low” or “0” signal in place of the weight data, effectively multiplying the weight data by a “0” value.

The Booth encoder 206, 300, 704 receiving the subset 202, 204 of bits “001” and/or “010” may generate and output the Booth encoded signal 208 of bits “000”, which may be configured to cause other parts of the CIM hardware 112a-112n, 500, 700 to execute multiplication of a “1” value with weight data, such as by a direct mapping of the weight data operation in the CIM hardware 112a-112n, 500, 700 to achieve the result of the multiplication. The CIM hardware 112a-112n, 500, 700 may be configured to interpret/be controlled by the Booth encoded signal 208 of bits “000” to perform direct mapping of the weight data. Direct mapping in the CIM hardware 112a-112n, 500, 700 may enable bits of the weight data to propagate in the CIM hardware 112a-112n, 500, 700 unchanged resulting in signals representative of the unchanged weight data, effectively multiplying the weight data by a “1” value.

The Booth encoder 206, 300, 704 receiving the subset 202, 204 of bits “011” may generate and output the Booth encoded signal 208 of bits “010”, which may be configured to cause other parts of the CIM hardware 112a-112n, 500, 700 to execute multiplication of a “2” value with weight data, such as by a direct mapping of the weight data operation and left shift operation (e.g., left shift by 1 bit in an adder) on the weight data in the CIM hardware 112a-112n, 500, 700 to achieve the result of the multiplication. The CIM hardware 112a-112n, 500, 700 may be configured to interpret/be controlled by the Booth encoded signal 208 of bits “010” to perform direct mapping and shifting of the weight data. Left shifting direct mapped weight data in the CIM hardware 112a-112n, 500, 700 may shift bits of the weight data by an amount that changes the bits of the weight data resulting in signals representative of the weight data multiplied by a “2” value.

The Booth encoder 206, 300, 704 receiving the subset 202, 204 of bits “100” may generate and output the Booth encoded signal 208 of bits “011”, which may be configured to cause other parts of the CIM hardware 112a-112n, 500, 700 to execute multiplication of a “−2” value with weight data, such as by an inversion of the weight data operation, an addition operation of a “1” value at a least significant bit of the inverted weight data, and left shift operation (e.g., left shift by 1 bit in an adder) on the sum in the CIM hardware 112a-112n, 500, 700 to achieve the result of the multiplication. The CIM hardware 112a-112n, 500, 700 may be configured to interpret/be controlled by the Booth encoded signal 208 of bits “011” to perform inversion of the weight data, addition to the weight data, and shifting of the weight data. Inverting bits of the weight data and addition of a “1” value at a least significant bit of the inverted bits of the weight data in the CIM hardware 112a-112n, 500, 700 may generate signals representative of a negative signed version of the weight data, effectively multiplying the weight data by a “−1” value. Left shifting the negative signed version of the weight data in the CIM hardware 112a-112n, 500, 700 may shift bits of the negative signed version of the weight data by an amount that changes the bits of the negative signed version of the weight data resulting in signals representative of the negative signed version of the weight data multiplied by a “2” value. Together, these operations may result in signals representative of the weight data multiplied by a “−2” value.

The Booth encoder 206, 300, 704 receiving the subset 202, 204 of bits “101” and/or “110” may generate and output the Booth encoded signal 208 of bits “001”, which may be configured to cause other parts of the CIM hardware 112a-112n, 500, 700 to execute multiplication of a “−1” value with weight data, such as by an inversion of the weight data operation and an addition operation of a “1” value at a least significant bit of the inverted weight data in the CIM hardware 112a-112n, 500, 700 to achieve the result of the multiplication. The CIM hardware 112a-112n, 500, 700 may be configured to interpret/be controlled by the Booth encoded signal 208 of bits “001” to perform inversion of the weight data and addition to the weight data. Inverting bits of the weight data and addition of a “1” value at a least significant bit of the inverted bits of the weight data in the CIM hardware 112a-112n, 500, 700 may generate signals representative of a negative signed version of the weight data, effectively multiplying the weight data by a “−1” value.

In block 806, the CIM device may output a Booth encoded signal 208 from the Booth encoder 206, 300, 704. In block 808, the CIM device may receive the Booth encoded the signal 208 and weight data at the Booth decoder 706. Receiving the Booth encoded the signal 208 and weight data may include receiving at one or more of the multiplexers 504a, 504b, 504c, 504d and/or the adders 506a, 506b.

In block 810, the CIM device may generate a partial product of a multiplication of the input data 200 and the weight data and/or inverse of the weight data (collectively referred to herein as weight data for the method 800) using the Booth encoded signal 208 and the weight data. In other words, rather than a direct multiplication of the values of the input data 200, such as the subsets 202, 204 of the input data 200, and the weight data, the multiplication may be of a representative value (e.g., 0, 1, 2, −1, −2) controlled by the Booth encoded signal 208, for example, as described with reference to block 804, and the weight data. Various different operations, such as logic gating of the weight data, direct mapping of the weight data, inverting of the weight data, left shifting of the weight data, and/or adding a “1” value to the lest significant bit of the left shifted weight data, may be used to implement the multiplication of the representative value and the weight data. In some embodiments, the Booth decoder 706, including one or more of the multiplexers 504a, 504b, 504c, 504d and/or the adders 506a, 506b, 508 may generate the partial product.

In block 812, the CIM device may output the partial product from the Booth decoder 706 and receive the partial product at the compressor 708. In block 814, the CIM device may generate a partial sum by adding received partial products. The compressor 708 may accumulate partial products and add the partial products to generate the partial sum. In some embodiments, the addition of the partial products may generate a carry value.

In block 816, the CIM device may output the partial sum from the compressor 708. In some embodiments, the CIM device may output the carry value from the compressor 708 along with the associated partial sum. In block 818, the CIM device may receive the partial sum at an adder. In some embodiments, the adder may be the carry-lookahead adder 710. In some embodiments, the CIM device may receive the carry value output along with the associated partial sum.

In block 820, the CIM device may generate a final product of the Booth multiplication of the input data 200 and the weight data. The adder may accumulate partial sums and add the partial sums to generate the final product. In some embodiments, the adder may add the partial sums and the carry values to generate the final product. In block 822, the CIM device may output the final product. For example, the CIM device may output the final product from the CIM hardware 112a-112n, 500, 700, including the adder, to other CIM hardware 112a-112n, any part of the memory 100 (e.g., memory unit 102, memory chip 104a-104n, memory unit 108a-108n, banks 106a-106n, memory array 110a-110n), and/or to a processor (e.g., central processing unit (CPU); not shown).

In some embodiments, the process of Booth multiplication in CIM using CIM hardware 112a-112n, 500, including any of a Booth encoder 206, 300, 704, a Booth decoder 706, a multiplexer 504a, 504b, 504c, 504d, an adder 506a, 506b, 508, a compressor 708, a carry-lookahead adder 710, and/or components thereof may be described by the following example. Booth encoded multiplication of an input data 200 X3, X2, X1, X0 by a weight data W may be expressed as addition of partial products of subsets 202, 204 X1, X0, 0 and X3, X2, X1 of the input data 200 each multiplied by the weight data. In other words, (X3, X2, X1, X0)* W=((X1, X0, 0)*W)+((X3, X2, X1)*W). The Booth encoded multiplication may simplify the input data 220 by Booth encoding subsets 202, 204 of the input data generating Booth encoded signals 208, as in block 804, and interpreting the Booth encoded signals 208 as instructions for operations to manipulate weight data, as in block 810. For example, a multiplicand (or input data 200) of 0111 may be appended with a 0 so that the multiplicand is 01110, and divided into subsets 202, 204 of 110 and 011 based on 3-bit Booth encoding of the multiplicand using bits X₂ᵢ₊₁, X₂ᵢ, and X₂ᵢ₋₁ per cycle, where “i” may be a number of a cycle iteration. As described herein, Booth encoding the subset 202, 204 of 110 may generate a Booth encoded signal configured to indicate multiplying the weight data by a “−1” value, such as by an inversion of the weight data operation and an addition operation of a “1” value at a least significant bit of the inverted weight data. Booth encoding the subset 202, 204 011 may generate a Booth encoded signal configured to indicate multiplying the weight data by a “2” value, such as by a direct mapping of the weight data operation and left shift operation (e.g., left shift by 1 bit in an adder) on the weight data. To achieve Booth encoded multiplication using the Booth encoded signals 208 and implementing the instructions for operations to manipulate weight data, the input data 200 may be converted to a format of an addition of 2's compliment values. For example, a serial of “1”s in the multiplicand (or input data 200) may be expressed as 01110=10000−00010. This subtraction may be considered as addition with a 2's complement number as 01110=10000−00010=10000+00010*(−1) (the multiplication by “−1” gives the 2's complement number). A Booth encoded multiplication of the multiplicand 01110 and a multiplier (or weight data) AAA may then be preformed as 01110×AAA=(10000−00010)×AAA=10000*AAA+00010×(AAA+1) (for which direct mapped weight data may be represented by “AAA”, the inverse weight data may be represented by “AAA” and the 2's compliment of the weight data may be given by (AAA+1)). Each resulting multiplication may generate a partial product result of manipulating weight data, as in block 810, that may be summed to generate partial sum, as in block 814. As illustrated by this example, the Booth encoding enables multiple bit subsets 202, 204 of the input data 200 may be multiplied by the weight data, rather than typical Booth multiplication which multiplies individual bits of the input data by the weight data to generate partial products that are summed to generate a final output. The Booth encoded multiplication described herein reduces the number of partial products calculated for the Booth multiplication, enabling the execution of Booth multiplication using fewer cycles, less time, and less area of computing hardware as compared to typical Booth multiplication.

Various examples (including, but not limited to, the examples discussed above with reference to FIGS. 1-8) may be implemented in any of a variety of computing devices, an example 900 of which is illustrated in FIG. 9. With reference to FIGS. 1-8, the wireless device 900 may include a processor 902 coupled to a touchscreen controller 904 and an internal memory 906 (e.g., memory 100). The processor 902 may be one or more multicore ICs designated for general or specific processing tasks. The internal memory 906 may be volatile or non-volatile memory and may also be secure and/or encrypted memory, or unsecure and/or unencrypted memory, or any combination thereof.

The touchscreen controller 904 and the processor 902 may also be coupled to a touchscreen panel 912, such as a resistive-sensing touchscreen, capacitive-sensing touchscreen, infrared sensing touchscreen, etc. The wireless device 900 may have one or more radio signal transceivers 908 (e.g., Peanut®, Bluetooth®, Zigbee®, Wi-Fi, RF radio) and antennas 910, for sending and receiving, coupled to each other and/or to the processor 902. The transceivers 908 and antennas 910 may be used with the above-mentioned circuitry to implement the various wireless transmission protocol stacks and interfaces. The wireless device 900 may include a cellular network wireless modem chip 916 that enables communication via a cellular network and is coupled to the processor.

The wireless device 900 may include a peripheral device connection interface 918 coupled to the processor 902. The peripheral device connection interface 918 may be singularly configured to accept one type of connection, or multiply configured to accept various types of physical and communication connections, common or proprietary, such as USB, FireWire, Thunderbolt, or PCIe. The peripheral device connection interface 918 may also be coupled to a similarly configured peripheral device connection port (not shown). The wireless device 900 may also include speakers 914 for providing audio outputs. The wireless device 900 may also include a housing 920, constructed of a plastic, metal, or a combination of materials, for containing all or some of the components discussed herein. The wireless device 900 may include a power source 922 coupled to the processor 902, such as a disposable or rechargeable battery. The rechargeable battery may also be coupled to the peripheral device connection port to receive a charging current from a source external to the wireless device 900.

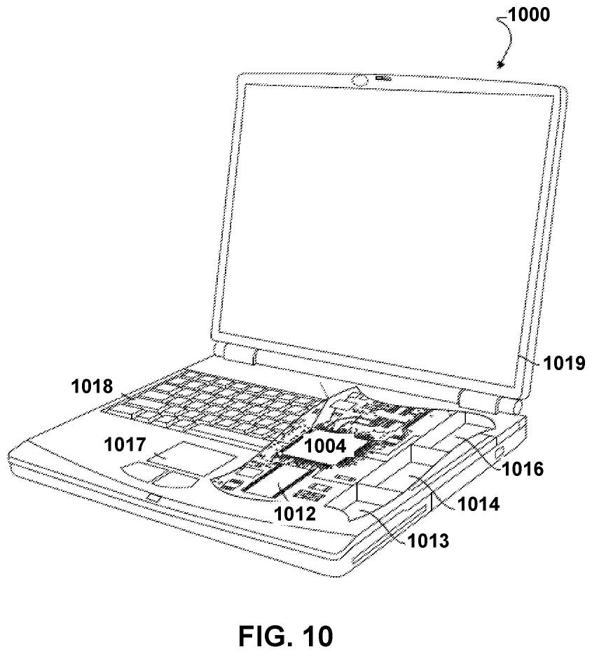

Various examples (including, but not limited to, the examples discussed above with reference to FIGS. 1-8), may also be implemented within a variety of personal computing devices, an example 1000 of which is illustrated in FIG. 10. With reference to FIGS. 1-8, the laptop computer 1000 may include a touchpad touch surface 1017 that serves as the computer's pointing device, and thus may receive drag, scroll, and flick gestures similar to those implemented on wireless computing devices equipped with a touchscreen display and described above. A laptop computer 1000 will typically include a processor 1004 coupled to volatile memory 1012 (e.g., memory 100) and a large capacity nonvolatile memory, such as a disk drive 1013 of Flash memory. The computer 1000 may also include a floppy disc drive 1014 and a compact disc (CD) drive 1016 coupled to the processor 1004. The computer 1000 may also include a number of connector ports coupled to the processor 1004 for establishing data connections or receiving external memory devices, such as a Universal Serial Bus (USB) or FireWire® connector sockets, or other network connection circuits for coupling the processor 1004 to a network. In a notebook configuration, the computer housing includes the touchpad 1017, the keyboard 1018, and the display 1019 all coupled to the processor 1004. Other configurations of the computing device may include a computer mouse or trackball coupled to the processor (e.g., via a USB input) as are well known, which may also be used in conjunction with various examples.

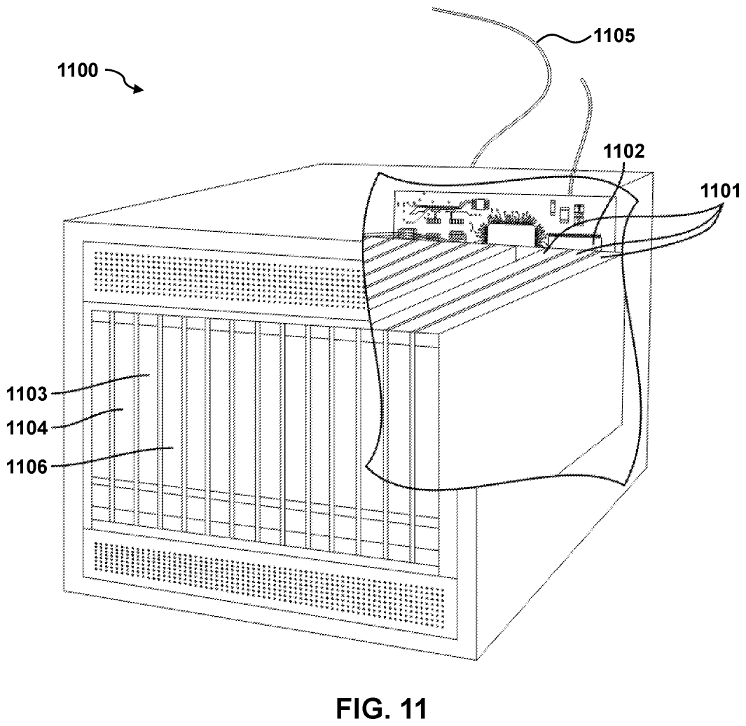

Various examples (including, but not limited to, the examples discussed above with reference to FIGS. 1-8) may also be implemented in fixed computing systems, such as any of a variety of commercially available servers. An example server 1100 is illustrated in FIG. 11. Such a server 1100 typically includes one or more multicore processor assemblies 1101 coupled to volatile memory 1102 (e.g., memory 100) and a large capacity nonvolatile memory, such as a disk drive 1104. As illustrated in FIG. 11, multicore processor assemblies 1101 may be added to the server 1100 by inserting them into the racks of the assembly. The server 1100 may also include a floppy disc drive, compact disc (CD) or digital versatile disc (DVD) disc drive 1106 coupled to the processor 1101. The server 1100 may also include network access ports 1103 coupled to the multicore processor assemblies 1101 for establishing network interface connections with a network 1105, such as a local area network coupled to other broadcast system computers and servers, the Internet, the public switched telephone network, and/or a cellular data network.

With reference to FIGS. 1-8, the processors 902, 1004, 1101 may be any programmable microprocessor, microcomputer or multiple processor chip or chips that can be configured by software instructions (applications) to perform a variety of functions, including the functions of various examples described above. In some devices, multiple processors may be provided, such as one processor dedicated to wireless communication functions and one processor dedicated to running other applications. Typically, software applications may be stored in the internal memory 906, 1012, 1013, 1102 before they are accessed and loaded into the processors 902, 1004, 1101. The processors 902, 1004, 1101 may include internal memory sufficient to store the application software instructions. In many devices the internal memory 906, 1012, 1013, 1102 may be a volatile or nonvolatile memory, such as flash memory, or a mixture of both. For the purposes of this description, a general reference to memory refers to memory accessible by the processors 902, 1004, 1101, including internal memory 906, 1012, 1013, 1102 or removable memory plugged into the device and memory 906, 1012, 1102 within the processors 902, 1004, 1101, themselves.

Referring to FIGS. 1-8, various embodiments provide a compute-in-memory device, that may include: a Booth encoder 300 configured to receive at least one input of first bits; and a Booth decoder 706 configured to receive at least one weight of second bits and to output a plurality of partial products of the at least one input and the at least one weight. In one embodiment, the compute-in-memory device may also include: an adder (e.g., 506a) configured to add a first partial product of the plurality of the partial products and a second partial product of the plurality of partial products before the Booth decoder 706 generates a third partial product of the plurality of the partial products and to generate a plurality of sums of partial products; and a carry-lookahead adder 710 configured to add the plurality of sums of partial products and to generate a final sum. In one embodiment, the Booth encoder 300 may include: an XOR gate 302 configured to receive a first bit and a second bit of the at least one input; an XNOR gate 308 configured to receive the second bit and a third bit of the at least one input; a first NOR gate 304 configured to receive an output of the XOR gate 302 and an output of the XNOR gate 308 and to output a Booth encoded bit; a second NOR gate 306 configured to receive the output of the first XOR gate 302 and the Booth encoded bit and to output an enable signal configured to control logic gating of the Booth decoder 706; a third NOR gate 310 configured to receive the enable signal and an inverse of the third bit of the input and to output a select signal. In one embodiment, the second bit may be a more significant bit of the at least one input than the first bit; and the third bit may be a most significant bit of the at least one input. In one embodiment, the Booth decoder 706 may include: a plurality of multiplexers 504; and a plurality of adders 506. In one embodiment, a first multiplexer (e.g., 504a) of the plurality of multiplexers 504 may be configured to receive a select signal from the Booth encoder 300, a first number of bits of the at least one weight and a first number of inverted bits of the at least one weight, and to selectively output the first number of bits of the at least one weight or the first number of inverted bits of the at least one weight based on the select signal. In one embodiment, a adder (e.g., 506a) of the plurality of adders 506 is configured to: receive an enable signal and a Booth encoded bit of the at least one input from the Booth encoder 300; receive a first number of bits of the at least one weight or a first number of inverted bits of the at least one weight from a first multiplexer (e.g., 504a) of the plurality of multiplexers 504; and execute an operation on the first number of bits of the at least one weight or the first number of inverted bits of the at least one weight based on the enable signal or the Booth encoded bit of the at least one input. In one embodiment, the first adder (e.g., 506a) may be configured such that executing an operation on the first number of bits of the at least one weight or the first number of inverted bits of the at least one weight based on the enable signal or the Booth encoded bit of the at least one input includes logic gating the first adder (e.g., 506a) based on the enable signal. In one embodiment, the first adder (e.g., 506a) includes a shifter 508, and the first adder (e.g., 506a) may be configured such that executing an operation on the first number of bits of the at least one weight or the first number of inverted bits of the at least one weight based on the enable signal or the Booth encoded bit of the at least one input includes shifting, by the shifter 508, the first number of bits of the at least one weight or the first number of inverted bits of the at least one weight based on the based on the Booth encoded bit. In one embodiment, the first adder (e.g., 506a) may be configured to receive a select signal from the Booth encoder 300; and add a 1 bit to the least significant bit of the first number of inverted bits of the at least one weight based on the select signal. In one embodiment, the first adder (e.g., 506a) is configured to receive outputs of at least two multiplexers (e.g., 504a, 504b) of the plurality of multiplexers 504 and add outputs of the at least two multiplexers (e.g., 504a, 504b) to generate at least part of the plurality of partial products.

Referring to FIGS. 1-8, various embodiments provide a memory system 100, including compute-in-memory hardware 112 that may include: a Booth encoder 300 having: an exclusive OR gate 302 coupled to a first data input line and a second data input line at inputs of the exclusive OR gate; an exclusive NOR gate 308 coupled to the second data input line and a third data input line at inputs of the exclusive NOR gate; a first NOR gate 304 coupled to an output of the exclusive OR gate 302 and an output of the exclusive NOR gate 308 at inputs of the first NOR gate 304; a second NOR gate 306 coupled to the output of the exclusive OR gate 302 and an output of the first NOR gate 304 at inputs of the second NOR gate 306; and a third NOR gate 310 coupled to an output of the second NOR gate 306 at an input of the third NOR gate 310 and coupled to the third data input line at an inverted input of the third NOR gate 310; and a Booth decoder 706 having: a plurality of multiplexers 504 coupled to weight data input lines and an output of the third NOR gate 310; and a plurality of adders 506, wherein a first adder (e.g., 506a) of the plurality of adders 506 is coupled to outputs of a subset of the plurality of multiplexers (e.g., 504a), the output of the first NOR gate 304, the output of the second NOR gate 306, and the output of the third NOR gate 310.

Referring to FIGS. 1-8, various embodiments provide a method of Booth multiplication in a compute-in-memory device. The method of Booth multiplication may include: Booth encoding a plurality of subsets 202, 204 of an input data 200 generating a plurality of Booth encoded signals 208 by a Booth encoder 206, 300 of the compute-in-memory device; and operating on a weight by a Booth decoder 706 of the compute-in-memory device generating a portion of a partial product, wherein operations for operating on the weight are designated by the plurality of Booth encoded signals 208. In one embodiment, operating on the weight by the Booth decoder 706 may include logic gating the weight. In one embodiment, operating on the weight by the Booth decoder 706 may include directly mapping the weight generating a directly mapped weight. In one embodiment, operating on the weight by the Booth decoder 706 further comprises left shifting the directly mapped weight. In one embodiment, operating on the weight by the Booth decoder 706 comprises inverting the weight generating an inverted weight. In one embodiment, operating on the weight by the Booth decoder 706 further comprises left shifting the inverted weight. In one embodiment, operating on the weight by the Booth decoder 706 further comprises adding a “1” value to a least significant bit of the inverted weight. In one embodiment, the method may also include: adding a plurality of portions of the partial product, including the portion of the partial product, generating the partial product; and adding a plurality of partial products, including the partial product, prior to generating all partial products of a Booth multiplication of the plurality of subsets 202, 204 of an input data 200 and the weight.

The foregoing method descriptions and the process flow diagrams are provided merely as illustrative examples and are not intended to require or imply that the steps of various examples must be performed in the order presented. As will be appreciated by one of skill in the art the order of steps in the foregoing examples may be performed in any order. Words such as “thereafter,” “then,” “next,” etc. are not intended to limit the order of the steps; these words are simply used to guide the reader through the description of the methods. Further, any reference to claim elements in the singular, for example, using the articles “a,” “an” or “the” is not to be construed as limiting the element to the singular.

The various illustrative logical blocks, processes, circuits, and algorithm steps described in connection with the examples disclosed herein may be implemented as electronic hardware, computer software, or combinations of both. To clearly illustrate this interchangeability of hardware and software, various illustrative components, blocks, processes, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the various embodiments disclosed herein.

The preceding description of the disclosed examples is provided to enable any person skilled in the art to make or use the various embodiments disclosed herein. Various modifications to these examples will be readily apparent to those skilled in the art, and the generic principles defined herein may be applied to other examples without departing from the spirit or scope of the invention. Thus, the various embodiments disclosed herein are not intended to be limited to the examples shown herein but is to be accorded the widest scope consistent with the following claims and the principles and novel features disclosed herein.

As described herein, one skilled in the art will realize that examples of dimensions are approximate values and may vary by +/−5.0%, as required by manufacturing, fabrication, and design tolerances.

Various embodiments and examples are described herein in terms of electric voltage or electric current. One skilled in the art will realize that such embodiments and examples may be similarly implemented in terms of the other of electric voltage or electric current.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A compute-in-memory device, comprising:
a Booth encoder configured to receive at least one input of first bits; and
a Booth decoder configured to receive at least one weight of second bits and to output a plurality of partial products of the at least one input and the at least one weight.

2. The compute-in-memory device of claim 1, further comprising:
an adder configured to add a first partial product of the plurality of partial products and a second partial product of the plurality of partial products before the Booth decoder generates a third partial product of the plurality of the partial products and to generate a plurality of sums of partial products; and
a carry-lookahead adder configured to add the plurality of sums of partial products and to generate a final sum.

3. The compute-in-memory device of claim 1, wherein the Booth encoder includes:
an XOR gate configured to receive a first bit and a second bit of the at least one input;
an XNOR gate configured to receive the second bit and a third bit of the at least one input;
a first NOR gate configured to receive an output of the XOR gate and an output of the XNOR gate and to output a Booth encoded bit;
a second NOR gate configured to receive the output of the first XOR gate and the Booth encoded bit and to output an enable signal configured to control logic gating of the Booth decoder;
a third NOR gate configured to receive the enable signal and an inverse of the third bit of the at least one input and to output a select signal.

4. The compute-in-memory device of claim 3, wherein:
the second bit is a more significant bit of the at least one input than the first bit; and
the third bit is a most significant bit of the at least one input.

5. The compute-in-memory device of claim 1, wherein the Booth decoder includes:
a plurality of multiplexers; and
a plurality of adders.

6. The compute-in-memory device of claim 5, wherein a first multiplexer of the plurality of multiplexers is configured to receive a select signal from the Booth encoder, a first number of bits of the at least one weight and a first number of inverted bits of the at least one weight, and to selectively output the first number of bits of the at least one weight or the first number of inverted bits of the at least one weight based on the select signal.

7. The compute-in-memory device of claim 5, wherein a first adder of the plurality of adders is configured to:
receive an enable signal and a Booth encoded bit of the at least one input from the Booth encoder;
receive a first number of bits of the at least one weight or a first number of inverted bits of the at least one weight from a first multiplexer of the plurality of multiplexers; and
execute an operation on the first number of bits of the at least one weight or the first number of inverted bits of the at least one weight based on the enable signal or the Booth encoded bit of the at least one input.

8. The compute-in-memory device of claim 7, wherein the first adder is configured such that executing an operation on the first number of bits of the at least one weight or the first number of inverted bits of the at least one weight based on the enable signal or the Booth encoded bit of the at least one input includes logic gating the first adder based on the enable signal.

9. The compute-in-memory device of claim 7, wherein the first adder includes a shifter, and wherein the first adder is configured such that executing an operation on the first number of bits of the at least one weight or the first number of inverted bits of the at least one weight based on the enable signal or the Booth encoded bit of the at least one input includes shifting, by the shifter, the first number of bits of the at least one weight or the first number of inverted bits of the at least one weight based on the based on the Booth encoded bit.

10. The compute-in-memory device of claim 7, wherein the first adder is further configured to:
receive a select signal from the Booth encoder; and
add a 1 bit to the least significant bit of the first number of inverted bits of the at least one weight based on the select signal.

11. The compute-in-memory device of claim 7, wherein the first adder is configured to:
receive outputs of at least two multiplexers of the plurality of multiplexers and;
add outputs of the at least two multiplexers to generate at least part of the plurality of partial products.

12. A memory device, comprising compute-in-memory hardware including:
a Booth encoder having:
an exclusive OR gate coupled to a first data input line and a second data input line at inputs of the exclusive OR gate;
an exclusive NOR gate coupled to the second data input line and a third data input line at inputs of the exclusive NOR gate;
a first NOR gate coupled to an output of the exclusive OR gate and an output of the exclusive NOR gate at inputs of the first NOR gate;
a second NOR gate coupled to the output of the exclusive OR gate and an output of the first NOR gate at inputs of the second NOR gate; and
a third NOR gate coupled to an output of the second NOR gate at an input of the third NOR gate and coupled to the third data input line at an inverted input of the third NOR gate; and
a Booth decoder having:
a plurality of multiplexers coupled to weight data input lines and an output of the third NOR gate; and
a plurality of adders, wherein a first adder of the plurality of adders is coupled to outputs of a subset of the plurality of multiplexers, the output of the first NOR gate, the output of the second NOR gate, and the output of the third NOR gate.

13. A method of Booth multiplication in a compute-in-memory device, comprising:
Booth encoding a plurality of subsets of an input data generating a plurality of Booth encoded signals by a Booth encoder of the compute-in-memory device; and
operating on a weight by a Booth decoder of the compute-in-memory device generating a portion of a partial product, wherein operations for operating on the weight are designated by the plurality of Booth encoded signals.

14. The method of claim 13, wherein operating on the weight by the Booth decoder comprises logic gating the weight.

15. The method of claim 13, wherein operating on the weight by the Booth decoder comprises directly mapping the weight generating a directly mapped weight.

16. The method of claim 15, wherein operating on the weight by the Booth decoder further comprises left shifting the directly mapped weight.

17. The method of claim 13, wherein operating on the weight by the Booth decoder comprises inverting the weight generating an inverted weight.

18. The method of claim 17, wherein operating on the weight by the Booth decoder further comprises left shifting the inverted weight.

19. The method of claim 17, wherein operating on the weight by the Booth decoder further comprises adding a “1” value to a least significant bit of the inverted weight.

20. The method of claim 13, further comprising:
adding a plurality of portions of the partial product, including the portion of the partial product, generating the partial product; and
adding a plurality of partial products, including the partial product, prior to generating all partial products of a Booth multiplication of the plurality of subsets of an input data and the weight.
